(19) United States
(12) Patent Application Publication
(10) Pub. No.: US 2018/0086943 A1
(43) Pub. Date: Mar. 29, 2018

(54) TREATMENT COMPOSITION FOR CHEMICAL MECHANICAL POLISHING, CHEMICAL MECHANICAL POLISHING METHOD, AND CLEANING METHOD

(71) Applicant: JSR CORPORATION, Minato-ku (JP)

(72) Inventors: Takahiro HAYAMA, Minato-ku (JP); Ran MITSUBOSHI, Minato-ku (JP); Yasutaka KAMEI, Minato-ku (JP); Naoki NISHIGUCHI, Minato-ku (JP); Kiyotaka MITSUMOTO, Minato-ku (JP); Satoshi KAMO, Minato-ku (JP); Masashi IIDA, Minato-ku (JP)

(73) Assignee: JSR CORPORATION, Minato-ku (JP)

(21) Appl. No.: 15/563,076

(22) PCT Filed: Mar. 24, 2016
(86) PCT No.: PCT/JP2016/059324

§ 371 Date: Sep. 29, 2017

(30) Foreign Application Priority Data
Mar. 30, 2015 (JP) 2015-068355

(51) Int. Cl. C09G 1/04; H01L 21/48; C23F 1/00; B24B 37/20; B24B 57/02; C09G 1/02

(52) U.S. Cl. CPC C09G 1/04; H01L 21/4864; H01L 21/4846; H01L 23/49866; B24B 37/20; B24B 57/02; C09G 1/02; C23F 1/00

(57) ABSTRACT

A treatment composition for chemical mechanical polishing includes: (A) a water-soluble amine; (B) a water-soluble polymer having an aromatic hydrocarbon group-containing repeating unit; and an aqueous medium. The treatment composition for chemical mechanical polishing preferably further includes (C) an organic acid having an aromatic hydrocarbon group and has a pH of 9 or more.

### TECHNICAL FIELD

The present invention relates to a treatment composition for chemical mechanical polishing, a chemical mechanical polishing method, and a cleaning method.

### BACKGROUND ART

Chemical mechanical polishing (CMP) has rapidly spread into wide use, for example, as a planarization technology in the production of a semiconductor device. The CMP is a technology involving pressing an object to be polished against a polishing pad, and causing the object to be polished and the polishing pad to slide with respect to each other while supplying an aqueous dispersion for chemical mechanical polishing onto the polishing pad, to thereby chemically and mechanically polish the object to be polished.

In recent years, along with miniaturization of the semiconductor device, a wiring layer including wiring, a plug, and the like formed in the semiconductor device has been increasingly fine a planarization method through the chemical mechanical polishing has been used for the wiring layer. A wiring board in the semiconductor device includes: a wiring material, and a barrier metal material for preventing diffusion of the wiring material into an inorganic material film. Major wiring materials, which have been used, are copper and tungsten, and major barrier metal materials, which have been used, are tantalum nitride and titanium nitride. For example, on a wiring board having a surface on which copper coexists with tantalum nitride and titanium nitride, it is necessary to remove a metal film redundantly laminated on a semiconductor substrate through CMP without causing both the wiring material and the barrier metal material to corrode. Similarly, after CMP, it is necessary to remove a copper oxide film or an organic residue on the surface of the wiring board without causing both the wiring material and the barrier metal material to corrode. In view of the foregoing, for example, there is proposed a slurry containing a compound having a phosphonate group or a carboxylate group as a cobalt oxidizing agent (see, for example, Patent Literature 1). In addition, an acidic treatment agent for chemical mechanical polishing capable of suppressing the corrosion of the barrier metal material is often used, and for example, an acidic cleaning agent has gone mainstream (see, for example, Patent Literature 2).

In recent years, along with extremely high integration of the semiconductor device, even contamination with an extremely small amount of impurities has largely affected the performance of the device, and by extension, a product yield. For example, on the surface of an uncleaned 8-inch wafer after completion of CMP, the number of particles each having a diameter of 0.2 μm or more to be counted is 10,000 or more, and there is a demand for removal of the particles to several to dozens of pieces through cleaning. In addition, the concentration of metal impurities (the number of impurity atoms per square centimeter) on the surface is from 1×10¹¹ to 1×10¹² or more, and there is a customer demand for removal of the metal impurities to 1×10¹⁰ or less through the cleaning. Therefore, when CMP is introduced in the production of the semiconductor device, the cleaning after CMP is an inevitable and essential step.

However, in advanced node semiconductor substrates, copper wiring has become finer, and cobalt, which has good adhesiveness to copper and can be formed into a thin film, has been used instead of the hitherto known barrier metal material. Cobalt is easily eluted under acidic conditions, and besides, corrosion in an acid solution, which has not hitherto posed a major problem, has largely affected the yield in the finer copper wiring. In view of the foregoing, neutral to alkaline cleaning agents have recently come into use (see, for example, Patent Literature 3).

### CITATION LIST

### Patent Literature

PTL 1: WO2014-132641

PTL 2: JP2010-258014

PTL 3: JP2009-055020

### SUMMARY OF INVENTION

### Technical Problem

However, the related-art chemical mechanical polishing composition fails to successfully achieve a sufficient cobalt polishing rate and reduction in cobalt corrosion at the same time. In addition, while a surfactant or the like is used to protect cobalt in some cases, there is another problem in that the surfactant adsorbs onto the surface of copper as well, and hence a sufficient copper polishing rate is difficult to achieve.

In addition, while the related-art neutral to alkaline cleaning agents are effective in removing foreign matter and against elution of metal wiring, protection of the barrier metal material (in particular, a cobalt film) is insufficient, and corrosion of the barrier metal material poses a major problem. In addition, it has been reported that the use of the related-art alkaline cleaning agent entails the occurrence of defects on a pattern wafer after cleaning.

Thus, according to some aspects of the present invention, there are provided a treatment composition for chemical mechanical polishing, which enables planarization of a wiring layer through chemical mechanical polishing while suppressing the corrosion of a wiring material and a barrier metal material to be used in a wiring board and the occurrence of defects at the same time, and can efficiently remove a metal oxide film and an organic residue on the wiring board by solving at least part of the above-mentioned problems, and a polishing method and cleaning method for a wiring board using the treatment composition for chemical mechanical polishing.

### Solution to Problem

The present invention has been made in order to solve at least part of the above-mentioned problems, and can be realized as the following aspects or application examples.

### Application Example 1

A treatment composition for chemical mechanical polishing of a wiring board according to one aspect of the present invention includes:

(A) a water-soluble amine;

(B) a water-soluble polymer having an aromatic hydrocarbon group-containing repeating unit; and

an aqueous medium.

### Application Example 2

In the above-mentioned Application Example, the treatment composition for chemical mechanical polishing may further include (C) an organic acid having an aromatic hydrocarbon group.

### Application Example 3

In the above-mentioned Application Examples, the treatment composition for chemical mechanical polishing may have a pH of 9 or more.

### Application Example 4

In the above-mentioned Application Examples, the component (A) may include at least one kind selected from the group consisting of alkanolamines, hydroxylamine, morpholine, morpholine derivatives, piperazine, and piperazine derivatives.

### Application Example 5

In the above-mentioned Application Examples, the component (B) may include a polymer having a structural unit derived from alkyl group-substituted or unsubstituted styrene.

### Application Example 6

In the above-mentioned Application Examples, the component (C) may include at least one kind selected from the group consisting of phenylsuccinic acid, phenylalanine, benzoic acid, phenyllactic acid, and naphthalenesulfonic acid.

### Application Example 7

In the above-mentioned Application Examples,

the treatment composition for chemical mechanical polishing may be used for treating a surface to be treated of a wiring board, and

the wiring board may include, on the surface to be cleaned:
a wiring material including copper or tungsten; and
a barrier metal material including at least one kind selected from the group consisting of tantalum, titanium, cobalt, ruthenium, manganese, and compounds thereof.

### Application Example 8

In the above-mentioned Application Example, the surface to be cleaned may include a site in which the wiring material and the barrier metal material are brought into contact with each other.

### Application Example 9

In the above-mentioned Application Examples, the treatment composition for chemical mechanical polishing may be a cleaning composition for cleaning the surface to be treated.

### Application Example 10

In the above-mentioned Application Examples, the treatment composition for chemical mechanical polishing may further include (D) abrasive grains.

### Application Example 11

In the above-mentioned Application Example, the treatment composition for chemical mechanical polishing may be a chemical mechanical polishing composition for polishing the surface to be treated.

### Application Example 12

A chemical mechanical polishing method according to one aspect of the present invention includes polishing the surface to be treated with the treatment composition for chemical mechanical polishing of the above-mentioned Application Example 11.

### Application Example 13

A cleaning method according to one aspect of the present invention includes cleaning the surface to be treated with the treatment composition for chemical mechanical polishing of the above-mentioned Application Example 9.

### Advantageous Effects of Invention

The treatment composition for chemical mechanical polishing according to the present invention enables planarization of a wiring layer through chemical mechanical polishing while suppressing the corrosion of a wiring material and a barrier metal material to be used in a wiring board and the occurrence of defects at the same time. A metal oxide film and an organic residue on the wiring board by can also be efficiently removed.

### BRIEF DESCRIPTION OF DRAWINGS

FIG. 1 is a sectional view for schematically illustrating an object to be treated to be subjected to a chemical mechanical polishing method according to an embodiment of the present invention.

FIG. 2 is a sectional view for schematically illustrating the object to be treated after completion of a first polishing step.

FIG. 3 is a sectional view for schematically illustrating the object to be treated after completion of a second polishing step.

### DESCRIPTION OF EMBODIMENTS

Preferred embodiments of the present invention are described in detail below. The present invention is not limited to the following embodiments, and includes various modification examples performed within the range not changing the gist of the present invention.

### 1. Treatment Composition for Chemical Mechanical Polishing

A treatment composition for chemical mechanical polishing according to an embodiment of the present invention contains (A) a water-soluble amine (hereinafter also referred to as “component (A)”), (B) a water-soluble polymer having an aromatic hydrocarbon group-containing repeating unit (hereinafter also referred to as “component (B)”), and an aqueous medium.

The treatment composition for chemical mechanical polishing according to this embodiment may be used as a “chemical mechanical polishing composition” for polishing a surface to be treated. In this case, the treatment composition for chemical mechanical polishing preferably contains (D) abrasive grains (hereinafter also referred to as “component (D)”). The treatment composition for chemical mechanical polishing according to this embodiment may be used in, for example, a damascene process involving depositing a conductive metal, such as aluminum, copper, or tungsten, in fine trenches or vias provided on an insulating film of silicon oxide or the like on a semiconductor substrate by a sputtering method, a plating method, or the like, followed by removing a redundantly laminated metal film through CMP, to thereby leave the metal only in the fine trenches or vias. The treatment composition for chemical mechanical polishing according to this embodiment exhibits a particularly excellent effect in polishing treatment for a wiring board on which copper serving as a wiring material and cobalt and/or tantalum nitride serving as a barrier metal material coexist.

The treatment composition for chemical mechanical polishing according to this embodiment may also be used as a “cleaning composition” for cleaning the surface to be treated. In this case, its major use may be as a cleaning agent for removing particles or metal impurities present on the surfaces of the wiring material and barrier metal material after completion of CMP. In addition, when the treatment composition for chemical mechanical polishing according to this embodiment is used as the cleaning composition, an oxide film or an organic residue on a wiring board can efficiently be removed while the corrosion of the wiring material and barrier metal material and the occurrence of defects are suppressed at the same time. As described above, the treatment composition for chemical mechanical polishing according to this embodiment, when used as the cleaning composition, exhibits a particularly excellent effect in cleaning treatment for the wiring board on which copper serving as a wiring material and cobalt and/or tantalum nitride serving as a barrier metal material coexist.

Components contained in the treatment composition for chemical mechanical polishing according to this embodiment are described in detail below.

### 1.1. (A) Water-Soluble Amine

The treatment composition for chemical mechanical polishing according to this embodiment contains (A) a water-soluble amine. The inventors of the present invention presume that the component (A) functions as a so-called etching agent. The treatment composition for chemical mechanical polishing according to this embodiment, which contains the component (A), can remove a metal oxide film (for example, a CuO layer, a Cu₂O layer, and a Cu(OH)₂ layer) or an organic residue (for example, a BTA layer) on the wiring board through etching in a polishing step in CMP and in a cleaning step after completion of CMP.

The term “water-soluble” as used in the present invention refers to a case in which the mass of a substance dissolved in 100 g of water at 20° C. is 0.1 g or more.

The component (A) is not particularly limited, but specific examples thereof include an alkanolamine, a primary amine, a secondary amine, and a tertiary amine.

The alkanolamine is not particularly limited, but specific examples thereof include monoethanolamine, diethanolamine, triethanolamine, N-methylethanolamine, N-methyl-N,N-diethanolamine, N,N-dimethylethanolamine, N,N-diethylethanolamine, N,N-dibutylethanolamine, N-(β-aminoethyl)ethanolamine, N-ethylethanolamine, monopropanolamine, dipropanolamine, tripropanolamine, monoisopropanolamine, diisopropanolamine, and triisopropanolamine. The primary amine is not particularly limited, but specific examples thereof include methylamine, ethylamine, propylamine, butylamine, pentylamine, and 1,3-propanediamine. The secondary amine is not particularly limited, but specific examples thereof include piperidine and piperazine. Examples of the tertiary amine include trimethylamine and triethylamine. Those components (A) may be used alone or as a mixture thereof.

Of those components (A), monoethanolamine and monoisopropanolamine are preferred, and monoethanolamine is more preferred from the viewpoint of a high etching effect on the metal oxide film or the organic residue on the wiring board.

When the treatment composition for chemical mechanical polishing according to this embodiment is used as the chemical mechanical polishing composition for polishing the surface to be treated, the content of the component (A) is preferably 0.0001 mass % or more and 1 mass % or less, more preferably 0.0005 mass % or more and 0.5 mass % or less, particularly preferably 0.001 mass % or more and 0.1 mass % or less with respect to the total mass of the chemical mechanical polishing composition. When the content of the component (A) falls within the above-mentioned range, more effective polishing can be achieved in the polishing step for wiring without a reduction in polishing rate while the metal corrosion on the wiring board is reduced.

When the treatment composition for chemical mechanical polishing according to this embodiment is used as the cleaning composition for cleaning the surface to be treated after the chemical mechanical polishing, the content of the component (A) is preferably 0.0001 mass % or more and 1 mass % or less, more preferably 0.0005 mass % or more and 0.5 mass % or less, particularly preferably 0.001 mass % or more and 0.1 mass % or less with respect to the total mass of the cleaning composition. When the content of the component (A) falls within the above-mentioned range, the metal oxide film or the organic residue on the wiring board can more effectively be removed through etching in the cleaning step after completion of CMP without corrosion of a surface to be cleaned.

### 1.2. (B) Water-Soluble Polymer

The treatment composition for chemical mechanical polishing according to this embodiment contains (B) a water-soluble polymer having an aromatic hydrocarbon group-containing repeating unit. The inventors of the present invention presume that the component (B) has a function of adsorbing onto a surface to be polished to reduce the corrosion. Therefore, the addition of the component (B) to the treatment composition for chemical mechanical polishing is considered to enable reduction of the corrosion on the surface to be treated.

The component (B) is not particularly limited as long as the polymer has an aromatic hydrocarbon group-containing repeating unit and is water-soluble. The polymer to be used in the component (B) is not particularly limited, but specific examples thereof include: a copolymer of a monomer, such as styrene, α-methylstyrene, or 4-methylstyrene, and an acid monomer, such as (meth)acrylic acid or maleic acid; and a polymer obtained by condensing benzenesulfonic acid, naphthalenesulfonic acid, or the like with formalin. Those components (B) may be used alone or in combination thereof.

The component (B) has a weight-average molecular weight (Mw) of preferably 1,000 or more and 1,500,000 or less, more preferably 3,000 or more and 1,200,000 or less. The term “weight-average molecular weight” as used herein refers to a weight-average molecular weight in terms of polyethylene glycol measured by gel permeation chromatography (GPC).

Molecular weight analysis conditions are as described below.

### <Measurement of Molecular Weight>

The weight-average molecular weight (Mw), number-average molecular weight (Mn), and molecular weight distribution (Mw/Mn) of the polymer were measured under the conditions described below by a gel permeation chromatography method.

Column: Columns “TSKgel αM” and “TSKgel α2500”, manufactured by Tosoh Corporation, are connected in series. Each of the columns has a size of 7.8 mm×300 mm.

Solvent: aqueous solution obtained by mixing 0.1 M sodium borate aqueous solution and acetonitrile at a ratio of 80:20 to become 100 in total

Flow rate: 0.8 ml/min

Temperature: 40° C.

Detection method: refractive index method

Standard substance: polyethylene oxide

GPC apparatus: manufactured by Tosoh Corporation, apparatus name “HLC-8020-GPC”

It is appropriate to adjust the content of the component (B) so that the viscosity of the treatment composition for chemical mechanical polishing is 2 mPa·s or less at normal temperature. When the viscosity of the treatment composition for chemical mechanical polishing is 2 mPa·s or less at normal temperature, the treatment composition for chemical mechanical polishing can be supplied on an abrasive cloth more effectively and stably. In addition, the viscosity depends almost entirely on the average molecular weights and content of the polymer, and hence it is appropriate to adjust the content of the component (B) in consideration of balance between these items.

When the treatment composition for chemical mechanical polishing according to this embodiment is used as the chemical mechanical polishing composition, the content of the component (B) is preferably 0.0001 mass % or more and 1 mass % or less, more preferably 0.0005 mass % or more and 0.1 mass % or less, particularly preferably 0.001 mass % or more and 0.01 mass % or less with respect to the total mass of the chemical mechanical polishing composition. When the content of the component (B) falls within the above-mentioned range, the surface to be treated can more effectively be polished without a reduction in polishing rate while the corrosion on the surface to be treated is reduced.

When the treatment composition for chemical mechanical polishing according to this embodiment is used as the cleaning composition, the content of the component (B) is preferably 0.0001 mass % or more and 1 mass % or less, more preferably 0.0005 mass % or more and 0.1 mass % or less, particularly preferably 0.001 mass % or more and 0.01 mass % or less with respect to the total mass of the cleaning composition. When the content of the component (B) falls within the above-mentioned range, particles or metal impurities contained in a CMP slurry can more effectively be removed from the wiring board while the corrosion is suppressed.

More specifically, the inventors of the present invention presume that the component (B) physically adsorbs onto the surface to be treated. It follows that, when the treatment composition for chemical mechanical polishing according to this embodiment is used in treatment of the surface to be treated including copper or the like, excessive corrosion of the surface to be treated caused by, for example, the amine compound serving as the etching agent is suppressed.

### 1.3. (C) Organic Acid

The treatment composition for chemical mechanical polishing according to this embodiment may contain (C) an organic acid having an aromatic hydrocarbon group (hereinafter also referred to as “component (C)”). The component (C) is a compound having at least one acid group, such as a carboxy group or a sulfo group, and an aromatic hydrocarbon group other than the acid group. However, the component (C) does not include any polymer.

The inventors of the present invention presume that the treatment composition for chemical mechanical polishing according to this embodiment is as follows. Specifically, when the component (C) is added, the component (C) adheres onto the surface of a metal, such as cobalt. The component (C) then helps the component (B) adhere onto the surface of the metal by virtue of affinity between the aromatic hydrocarbon group in the component (C) and the aromatic hydrocarbon group in the component (B), and serves to improve a suppressing effect on the corrosion. In addition, when a benzotriazole (BTA) layer is formed on the surface of the wiring material through CMP, a residue of the BTA layer can be reduced by effectively etching a CuO layer, a Cu₂O layer, and a Cu(OH)₂ layer, which have high affinity for the BTA layer. Further, the corrosion potentials of the wiring material and the barrier metal material on the wiring board can be controlled, and hence a difference in corrosion potential between the wiring material and the barrier metal material can be reduced. It follows that the corrosion of each metal caused by galvanic corrosion generated between dissimilar metals can be suppressed.

Herein, the “galvanic corrosion” is one form of corrosion caused by contact between dissimilar metals, and in general, refers to a phenomenon in which, when metals having different potentials are brought into contact with each other in an electrolytic solution, such as water, a metal having a lower potential corrodes. In particular, on the wiring board of a semiconductor device, the wiring material and the barrier metal material are brought into contact with each other, and hence there is a problem in that a metal having a lower potential, which is specific to a substance, selectively corrodes owing to a cell action in the presence of a cleaning liquid. However, when the component (C) is added to the treatment composition for chemical mechanical polishing according to this embodiment, the difference in corrosion potential between the wiring material and the barrier metal material can be reduced. As a result, the corrosion of each metal caused by galvanic corrosion generated between dissimilar metals can be suppressed.

The component (C) is not particularly limited, but specific examples thereof include benzoic acid, phenyllactic acid, phenylsuccinic acid, phenylalanine, and naphthalenesulfonic acid. Those components (C) may be used alone or as a mixture thereof.

When the treatment composition for chemical mechanical polishing according to this embodiment is used as the chemical mechanical polishing composition, the content of the component (C) is preferably 0.0001 mass % or more and 1 mass % or less, more preferably 0.0005 mass % or more and 0.5 mass % or less, particularly preferably 0.001 mass % or more and 0.1 mass % or less with respect to the total mass of the chemical mechanical polishing composition. When the content of the component (C) falls within the above-mentioned range, the surface to be treated can be polished without a reduction in polishing rate while the corrosion on the surface to be treated is reduced. In addition, the difference in corrosion potential between the wiring material and the barrier metal material on the wiring board can be reduced. As a result, the galvanic corrosion between the wiring material and the barrier metal material can be suppressed more effectively.

When the treatment composition for chemical mechanical polishing according to this embodiment is used as the cleaning composition, the content of the component (C) is preferably 0.0001 mass % or more and 1 mass % or less, more preferably 0.0005 mass % or more and 0.5 mass % or less, particularly preferably 0.001 mass % or more and 0.1 mass % or less with respect to the total mass of the cleaning composition. When the content of the component (C) falls within the above-mentioned range, the impurities or the residue of the BTA layer adhering onto the surface of the wiring material can be reduced. In addition, the difference in corrosion potential between the wiring material and the barrier metal material on the wiring board can be reduced. As a result, the galvanic corrosion between the wiring material and the barrier metal material can be suppressed more effectively.

### 1.4. (D) Abrasive Grains

When the treatment composition for chemical mechanical polishing according to this embodiment is used as the chemical mechanical polishing composition for polishing the object to be treated, the treatment agent for chemical mechanical polishing according to this embodiment may further contain (D) abrasive grains. The abrasive grains (D) are not particularly limited, but specific examples thereof include inorganic particles, such as silica particles, ceria particles, alumina particles, zirconia particles, and titania particles.

The silica particles are not particularly limited, but specific examples thereof include colloidal silica and fumed silica. Of those, colloidal silica is preferred. The colloidal silica is used preferably from the viewpoint of reducing polishing defects, such as a scratch, and for example, one produced by a method disclosed in JP2003-109921 may be used. In addition, colloidal silica surface modified by a method disclosed in JP2010-269985, J. Ind. Eng. Chem., Vol. 12, No. 6, (2006) 911-917, or the like may be used.

The content of the abrasive grains (D) is 0.1 mass % or more and 10 mass % or less, preferably 0.1 mass % or more and 8 mass % or less, more preferably 0.1 mass % or more and 7 mass % or less with respect to the total mass of the treatment composition for chemical mechanical polishing. When the content of the abrasive grains (D) falls within the above-mentioned range, a practical polishing rate of a tungsten film can be achieved.

### 1.5. pH Adjusting Agent

The treatment composition for chemical mechanical polishing according to this embodiment has a pH of preferably 9 or more, more preferably 10 or more and 14 or less, still more preferably 10.5 or more and 13.5 or less. When the treatment composition for chemical mechanical polishing has a pH of 9 or more, there is achieved a state in which a protective agent, such as the component (B) and the component (C) described above, and the etching agent easily function on the surface of the wiring board, and hence a satisfactory surface to be treated is easily obtained.

The treatment composition for chemical mechanical polishing according to this embodiment has a pH of preferably 9 or more as described above, and hence as a pH adjusting agent, it is preferred to use: an alkali metal hydroxide, such as sodium hydroxide, potassium hydroxide, rubidium hydroxide, or cesium hydroxide; an organic ammonium salt, such as tetramethylammonium hydroxide; or a basic compound, such as ammonia. Those pH adjusting agents may be used alone or as a mixture thereof.

Of those pH adjusting agents, an alkali metal hydroxide, such as sodium hydroxide, potassium hydroxide, rubidium hydroxide, or cesium hydroxide, is preferably used particularly in view of causing less health damage to human body. Potassium hydroxide is more preferred.

### 1.6. Aqueous Medium

The treatment composition for chemical mechanical polishing according to this embodiment contains an aqueous medium. The aqueous medium is not particularly limited as long as the medium contains water as a main component and can play a role as a solvent. Water is more preferably used as such aqueous medium.

### 1.7. Other Components

The treatment composition for chemical mechanical polishing according to this embodiment may further have added thereto a nonionic surfactant. The surfactant has an effect of imparting an appropriate viscosity to the treatment composition for chemical mechanical polishing. The viscosity of the treatment composition for chemical mechanical polishing is preferably adjusted to 0.5 mPa's or more and 2 mPa's or less at 25° C. In addition, when the treatment composition for chemical mechanical polishing according to this embodiment having added thereto the nonionic surfactant is used as the cleaning composition, the effect of removing particles or metal impurities contained in a CMP slurry from the wiring board is improved, and hence a more satisfactory surface to be treated is obtained in some cases.

Examples of the nonionic surfactant include: polyoxyethylene alkyl ethers, such as polyoxyethylene lauryl ether, polyoxyethylene cetyl ether, polyoxyethylene stearyl ether, and polyoxyethylene oleyl ether; polyoxyethylene aryl ethers, such as polyoxyethylene octyl phenyl ether and polyoxyethylene nonyl phenyl ether; sorbitan fatty acid esters, such as sorbitan monolaurate, sorbitan monopalmitate, and sorbitan monostearate; and polyoxyethylene sorbitan fatty acid esters, such as polyoxyethylene sorbitan monolaurate, polyoxyethylene sorbitan monopalmitate, and polyoxyethylene sorbitan monostearate. The nonionic surfactants shown as examples may be used alone or as a mixture thereof.

When the treatment composition for chemical mechanical polishing according to this embodiment is used as the chemical mechanical polishing composition, the content of the nonionic surfactant is preferably 0.001 mass % or more and 0.1 mass % or less, more preferably 0.002 mass % or more and 0.05 mass % or less, particularly preferably 0.003 mass % or more and 0.03 mass % or less with respect to the total mass of the chemical mechanical polishing composition. When the content of the nonionic surfactant falls within the above-mentioned range, the wiring layer can be more planarized through chemical mechanical polishing while the corrosion of the wiring material and barrier metal material to be used in the wiring board and the occurrence of defects are suppressed at the same time.

When the treatment composition for chemical mechanical polishing according to this embodiment is used as the cleaning composition, the content of the nonionic surfactant is preferably 0.001 mass % or more and 1.0 mass % or less, more preferably 0.002 mass % or more and 0.1 mass % or less, particularly preferably 0.003 mass % or more and 0.05 mass % or less with respect to the total mass of the cleaning composition. When the content of the nonionic surfactant falls within the above-mentioned range, the effect of removing particles or metal impurities contained in a CMP slurry from the wiring board is improved, and hence a more satisfactory surface to be cleaned is obtained in some cases.

### 1.8. Corrosion Potential

On the wiring board of a semiconductor device, the wiring material and the barrier metal material are brought into contact with each other, and hence in the presence of the treatment composition for chemical mechanical polishing, a metal having a lower potential, which is specific to a substance, selectively corrodes owing to a cell action. The inventors of the present invention presume that, in contrast to the foregoing, when the treatment composition for chemical mechanical polishing according to this embodiment is used in CMP or cleaning after CMP, the difference in corrosion potential between the wiring material and the barrier metal material can be reduced by virtue of interaction between the component (B) and the component (C), and hence the galvanic corrosion can be suppressed.

The treatment composition for chemical mechanical polishing according to this embodiment is presumed to exhibit a significantly high suppressing effect on the corrosion on the surface to be treated by such development mechanism as compared to the case of using the component (B) or the component (C) alone as a corrosion inhibitor.

Metal materials immersed in the treatment composition for chemical mechanical polishing according to this embodiment exhibit their specific corrosion potentials. However, in the treatment composition for chemical mechanical polishing according to this embodiment, the absolute value of a difference in corrosion potential between copper and cobalt can be reduced to 0.1 V or less, and the absolute value of a difference in corrosion potential between copper and tantalum nitride can be reduced to 0.5 V or less by virtue of the interaction between the component (B) and the component (C). Accordingly, it can be said that the treatment composition for chemical mechanical polishing according to this embodiment exhibits a particularly high suppressing effect on the galvanic corrosion on the wiring board using copper as the wiring material and cobalt and/or tantalum nitride as the barrier metal material.

The corrosion potential may be measured, for example, by the following procedure. First, an electrochemical measurement device in which three electrodes: a working electrode (WE) formed of a sample to be tested; a counter electrode (CE) for passing a current; and a reference electrode (RE) serving as a reference are electrically connected to a potentiostat is prepared. Next, the treatment composition for chemical mechanical polishing according to this embodiment is put in a cell, and the three electrodes are immersed in the treatment composition for chemical mechanical polishing in the cell. A potential is applied with the potentiostat, and a current is measured. The corrosion potential may be determined by measuring a potential-current curve.

### 1.9. Use

The treatment composition for chemical mechanical polishing according to this embodiment can be suitably used as the chemical mechanical polishing composition when the wiring board is polished through CMP. The wiring board to be polished preferably includes, on the surface to be polished: a wiring material including copper, cobalt, or tungsten; and a barrier metal material including at least one kind selected from the group consisting of tantalum, titanium, cobalt, ruthenium, manganese, and compounds thereof. Such wiring board can be polished without a reduction in polishing rate while the corrosion of the wiring material and barrier metal material and the occurrence of defects are suppressed at the same time.

In addition, the treatment composition for chemical mechanical polishing according to this embodiment can be suitably used as the cleaning agent for the wiring board when the wiring board after completion of CMP is cleaned. The wiring board to be cleaned preferably includes, on the surface to be cleaned: a wiring material including copper, cobalt, or tungsten; and a barrier metal material including at least one kind selected from the group consisting of tantalum, titanium, cobalt, ruthenium, manganese, and compounds thereof. In cleaning such a wiring board, the oxide film or the organic residue on the wiring board can efficiently be removed while the corrosion of the wiring material and barrier metal material and the occurrence of defects are suppressed at the same time.

In addition, the treatment composition for chemical mechanical polishing according to this embodiment can reduce the absolute value of a difference in corrosion potential between copper and cobalt to 0.1 V or less, and the absolute value of a difference in corrosion potential between copper and tantalum nitride to 0.5 V or less. Therefore, when a wiring board using copper as the wiring material and cobalt and/or tantalum nitride as the barrier metal material and including a site in which the wiring material and the barrier metal material are brought into contact with each other is polished or cleaned, the galvanic corrosion can effectively be suppressed.

### 1.10. Preparation Method for Treatment Composition for Chemical Mechanical Polishing

A preparation method for the treatment composition for chemical mechanical polishing according to this embodiment is not particularly limited, but an example thereof is a method involving adding the component (A) and the component (B), and as required, the component (C), the component (D), and the nonionic surfactant to the aqueous medium, and stirring and mixing the resultant to dissolve the components in the aqueous medium, followed by adding the pH adjusting agent thereto to adjust the pH to a predetermined value. The mixing order of the components other than the pH adjusting agent and the mixing method for the components are not particularly limited.

In addition, at the time of use, the treatment composition for chemical mechanical polishing according to this embodiment may be used by being diluted with the aqueous medium.

### 2. Treatment Method

A chemical mechanical polishing method and a cleaning method according to an embodiment of the present invention include a chemical mechanical polishing step and a cleaning step, respectively, involving using the above-mentioned treatment composition for chemical mechanical polishing. The chemical mechanical polishing method and the cleaning method according to this embodiment are not particularly limited, but specific examples thereof are described in detail below with reference to the drawings.

### 2.1. Production of Wiring Board

A wiring board to be subjected to the chemical mechanical polishing method or the cleaning method according to this embodiment includes: an insulating film in which a depression is formed; a barrier metal film which is formed so as to cover the bottom surface and side surface of the depression; and a metal oxide film which is buried in the depression so as to cover the barrier metal film and is to serve as wiring. In the wiring board, a material for the barrier metal film includes at least one kind selected from the group consisting of tantalum, titanium, cobalt, ruthenium, manganese, and compounds thereof, and a material for the metal oxide film buried in the depression includes copper or tungsten. As described below, the wiring board is obtained by subjecting an object to be treated to chemical mechanical polishing using the chemical mechanical polishing composition.

### 2.2. Object to be Treated

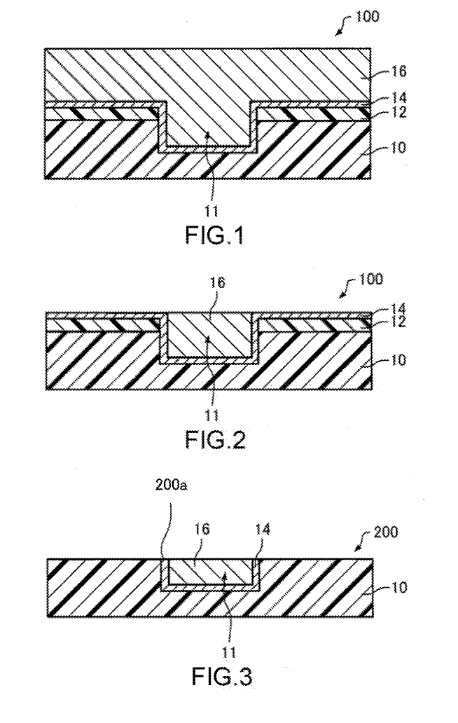

FIG. 1 is a sectional view for schematically illustrating an object to be treated to be used in chemical mechanical polishing. First, a production method for an object 100 to be treated illustrated in FIG. 1 is described.

(1) First, a low-dielectric-constant insulating film 10 is formed by an application method or a plasma CVD method. Examples of the low-dielectric-constant insulating film 10 include an inorganic insulating film and an organic insulating film. Examples of the inorganic insulating film include a SiOF film (k=3.5 to 3.7) and a Si—H-containing SiO₂ film (k=2.8 to 3.0). Examples of the organic insulating film include a carbon-containing SiO₂ film (k=2.7 to 2.9), a methyl group-containing SiO₂ film (k=2.7 to 2.9), a polyimide-based film (k=3.0 to 3.5), a parylene-based film (k=2.7 to 3.0), a Teflon (trademark)-based film (k=2.0 to 2.4), and an amorphous carbon (k=<2.5) (k in the parentheses represents a dielectric constant).

(2) An insulating film 12 is formed on the low-dielectric-constant insulating film 10 by a CVD method or a thermal oxidation method. The insulating film 12 is a film formed for protecting the low-dielectric-constant insulating film 10, which has low mechanical strength, from a polishing pressure or the like, and is a so-called cap layer. Examples of the insulating film 12 include a silicon oxide film formed by a vacuum process (e.g., a plasma enhanced-TEOS film (PETEOS film), a high density plasma enhanced-TEOS film (HDP film), an silicon oxide film obtained by a thermochemical vapor deposition method), an insulating film called fluorine-doped silicate glass (FSG), a borophosphosilicate film (BPSG film), an insulating film called silicon oxynitride (SiON), and silicon nitride.

(3) A wiring depression 11 is formed through etching so as to penetrate in both the low-dielectric-constant insulating film 10 and the insulating film 12.

(4) A barrier metal film 14 is formed by a CVD method so as to cover the surface of the insulating film 12 and the bottom surface and side surface of the wiring depression 11. As a material for the barrier metal film 14, there are given, for example, tantalum, titanium, cobalt, ruthenium, manganese, and compounds thereof. The barrier metal film 14 is often formed of one kind thereof, but two or more kinds thereof, such as tantalum (Ta) and tantalum nitride (TaN), may be used in combination. When a copper (or copper alloy) film is used as the metal oxide film 16, the barrier metal film 14 is preferably formed of Ta or TaN from the viewpoint of excellent bonding property to the copper (or copper alloy) film and excellent diffusion barrier property for the copper (or copper alloy) film.

(5) Further, metal is deposited on the barrier metal film 14, which is formed by a plating method, by a sputtering method, or the like, the object 100 to be treated is obtained. Examples of the metal for forming the metal oxide film 16 include copper (or a copper alloy) and tungsten.

### 2.3. Polishing Step

In this embodiment, chemical mechanical polishing is a technology involving pressing an object to be polished against a polishing pad, and causing the object to be polished and the polishing pad to slide with respect to each other while supplying the chemical mechanical polishing composition onto the polishing pad, to thereby chemically and mechanically polish the object to be polished.

FIG. 2 is a sectional view for schematically illustrating the object to be treated after completion of a first polishing step. FIG. 3 is a sectional view for schematically illustrating the object to be treated after completion of a second polishing step.

First, the unnecessary metal oxide film 16 deposited on the barrier metal film 14 of the object to be treated obtained in the section 2.2. is removed through CMP (first polishing step). In the first polishing step, a predetermined aqueous dispersion for chemical mechanical polishing, for example, an aqueous dispersion for chemical mechanical polishing containing abrasive grains, a carboxylic acid, an anionic surfactant, and the like is used to perform CMP. As illustrated in FIG. 2, the metal oxide film 16 is continued to be polished through CMP until the barrier metal film 14 is exposed, and CMP is stopped once after the exposure of the barrier metal film 14 is confirmed.

Next, the unnecessary barrier metal film 14 and the unnecessary metal oxide film 16 are removed through CMP (second polishing step). In the second polishing step, an aqueous dispersion for chemical mechanical polishing for the second polishing step, which is the same as or different from that used in the first polishing step, is used to perform CMP. As illustrated in FIG. 3, the unnecessary films are continued to be polished through CMP until the low-dielectric-constant insulating film 10 is exposed. By the above-mentioned procedure, a wiring board 200 excellent in smoothness on the surface to be polished is obtained.

A commercially available chemical mechanical polishing apparatus may be used in the chemical mechanical polishing described above. Examples of the commercially available chemical mechanical polishing apparatus include models “EPO-112” and “EPO-222” manufactured by Ebara Corporation, models “LGP-510” and “LGP-552” manufactured by Lapmaster SFT Corporation, and model “Mirra” manufactured by Applied Materials Inc.

Preferred polishing conditions are to be appropriately set depending on the chemical mechanical polishing apparatus to be used, but for example, the following conditions may be adopted when “EPO-112” is used as the chemical mechanical polishing apparatus.

Platen rotation speed: preferably from 30 rpm to 120 rpm, more preferably from 40 rpm to 100 rpm

Head rotation speed: preferably from 30 rpm to 120 rpm, more preferably from 40 rpm to 100 rpm

Ratio of platen rotation speed/head rotation speed: preferably from 0.5 to 2, more preferably from 0.7 to 1.5

Polishing pressure: preferably from 60 gf/cm² to 200 gf/cm², more preferably from 100 gf/cm² to 150 gf/cm²

Supply rate of treatment composition for chemical mechanical polishing: preferably from 50 mL/min to 400 mL/min, more preferably from 100 mL/min to 300 mL/min

### 2.4. Cleaning Step

Next, a surface (surface 200a to be cleaned) of the wiring board 200 illustrated in FIG. 3 is cleaned with the above-mentioned cleaning composition. As illustrated in FIG. 3, the surface 200a to be cleaned also includes a site in which the metal oxide film 16 formed of the wiring material and the barrier metal film 14 formed of the barrier metal material are brought into contact with each other.

A cleaning method is not particularly limited, but the cleaning step is performed by a method involving bringing the above-mentioned cleaning composition into direct contact with the wiring board 200. Examples of the method of bringing the cleaning composition into direct contact with the wiring board 200 include: a dipping method involving filling a cleaning bath with the cleaning composition and dipping the wiring board thereinto; a spin method involving rotating the wiring board at high speed while causing the cleaning composition to flow down to the wiring board from a nozzle; and a spray method involving spraying the cleaning composition to the wiring board to clean the wiring board. In addition, as a device for performing such method, for example, there are given: a batch cleaning device configured to simultaneously clean a plurality of wiring boards accommodated in a cassette; and a single-wafer cleaning device configured to clean one wiring board attached to a holder.

In the cleaning method according to this embodiment, the temperature of the cleaning composition is generally set to room temperature. However, the cleaning composition may be warmed within a range not impairing its performance. For example, the cleaning composition may be warmed to from about 40° C. to about 70° C.

In addition, it is preferred to use a cleaning method using a physical force in combination with the above-mentioned method of bringing the cleaning composition into direct contact with the wiring board 200. As a result, removability of contamination with particles adhering onto the wiring board 200 is improved, and hence a cleaning time can be shortened. Examples of the cleaning method using a physical force include scrub cleaning using a cleaning brush and ultrasonic cleaning.

Further, cleaning with ultrapure water or pure water may be performed before and/or after cleaning by the cleaning method according to this embodiment.

When the wiring board, after completion of CMP, having a surface on which the wiring material and the barrier metal material coexist is cleaned by the cleaning method according to this embodiment, the oxide film or the organic residue on the wiring board can efficiently be removed while the corrosion of the wiring material and barrier metal material is suppressed. In addition, in the cleaning method according to this embodiment, the cleaning composition capable of reducing differences in corrosion potential between copper and cobalt and between copper and tantalum nitride is used as described above, and hence a particularly excellent effect is exhibited in cleaning treatment for the wiring board on which copper serving as a wiring material and cobalt and/or tantalum nitride serving as a barrier metal material coexist.

### 3. Examples

The present invention is described by way of Examples, but the present invention is by no means limited to these Examples below. The terms “part(s)” and “%” in Examples are by mass, unless otherwise stated.

### 3.1. Chemical Mechanical Polishing Composition

### 3.1.1. Preparation of Chemical Mechanical Polishing Composition

Ion-exchanged water and components shown in Table 1 were put into a vessel made of polyethylene so as to achieve the respective concentrations shown in Table 1 as a chemical mechanical polishing composition, followed by stirring for 15 minutes. Potassium hydroxide and ion-exchanged water were added to the resultant mixture so that the total amount of all the constituent components of the chemical mechanical polishing composition was 100 parts by mass, to thereby adjust the resultant to achieve the final concentrations of the respective components and the final pH shown in Table 1. After that, the resultant was filtered with a filter having a pore diameter of 5 μm. Thus, chemical mechanical polishing compositions shown in Table 1 were obtained. In Table 1, the “component (A′)” represents a component used as a component other than the component (A) described in Claims instead of or in combination with the component (A). The same applies to the “component (B′)”.

### 3.1.2. Evaluation Method

### 3.1.2.1. Evaluation of Polishing Rate

A cobalt wafer test piece was measured for thickness in advance with a metal film thickness meter “RG-5” manufactured by NPS, Inc., and then subjected to chemical mechanical polishing treatment (CMP) for 1 minute under the polishing conditions of a platen rotation speed of 90 rpm, a head rotation speed of 90 rpm, a head pressing pressure of 3 psi, and a supply rate of the chemical mechanical polishing composition of 100 mL/min with the “LM-15C” model manufactured by Lap master SFT Ltd. as a polishing apparatus and “IC1000/K-Groove” manufactured by Rodel-Nitta Company as a polishing pad. After the polishing treatment, the cobalt wafer test piece was measured for thickness again with the metal film thickness meter “RG-5”, and a difference in thickness before and after the polishing, specifically, a reduction in thickness through the chemical mechanical polishing treatment was determined by calculation. A polishing rate was determined by calculation from the reduction in thickness and a polishing time. The evaluation criteria for a cobalt wafer polishing rate are as described below. The results are also shown in Table 1.

Good: A case of 100 Å/min or more is judged as a satisfactory result.
Poor: A case of less than 100 Å/min is judged as an unsatisfactory result.

### 3.1.2.2. Evaluation of Defects

An 8-inch wafer in which a cobalt film having a thickness of 2,000 Å was laminated on a silicon substrate was subjected to chemical mechanical polishing with a chemical mechanical polishing apparatus “EPO112” (manufactured by Ebara Corporation) under the following conditions.

Kind of chemical mechanical polishing composition: the chemical mechanical polishing composition shown in Table 1

Polishing pad: “IC1000/SUBA400” manufactured by Rodel-Nitta Company

Platen rotation speed: 70 rpm

Head rotation speed: 70 rpm

Head load: 250 g/cm²

Supply rate of chemical mechanical polishing composition: 200 mL/min

Polishing time: 60 seconds

### <Brush Scrub Cleaning>

Cleaning agent: “CLEAN-100” manufactured by Wako Pure Chemical Industries, Ltd.

Upper brush rotation speed: 100 rpm

Lower brush rotation speed: 100 rpm

Substrate rotation speed: 100 rpm

Cleaning agent supply amount: 300 mL/min

Cleaning time: 30 seconds

The substrate obtained above was measured for the number of defects on the entire surface to be treated with a wafer defect inspection system (KLA 235I, manufactured by KLA-Tencor Corporation). The evaluation criteria are as described below.

Good: A case in which the number of defects on the entire surface of the substrate (diameter: 8 inches) is 250 or less is judged as a satisfactory result.
Poor: A case in which the number of defects on the entire surface of the substrate (diameter: 8 inches) exceeds 250 is judged as an unsatisfactory result.

### 3.1.2.3. Evaluation of Corrosion of Cobalt

Corrosion was evaluated by counting the number of dots on the surface of the substrate obtained in the section 3.1.2.2. through its observation with an optical microscope. The evaluation criteria are as described below. The results are also shown in Table 1.

Good: A case in which the number of dots on the entire surface of the substrate (diameter: 8 inches) is 20 or less is judged as a satisfactory result.
Poor: A case in which the number of dots on the entire surface of the substrate (diameter: 8 inches) exceeds 20 is judged as an unsatisfactory result.

### 3.1.3. Evaluation Results

The compositions of the chemical mechanical polishing compositions, and the evaluation results are shown in Table 1 below.

TABLE 1

| | | Example | | | | | | | | |
|---|---|---|---|---|---|---|---|---|---|---|
| | | Concentration | | | Comparative Example | | | | | |
| | | (mass %) | | | Concentration (mass %) | | | | | |
| Chemical mechanical polishing composition | | 1 | 2 | 3 | 1 | 2 | 3 | 4 | 5 | 6 |
| Component (A) | Monoethanolamine | 0.05 | 0.3 | | | 0.3 | 0.3 | 0.2 | 0.1 | |
| | Monoisopropanolamine | | | 0.2 | | | | | | 0.1 |
| Component (A′) | Leucine | | | | 0.2 | | | | 0.01 | |
| | Sulfuric acid | | | | | | | 0.01 | | |
| Component (B) | Styrene-maleic acid copolymer | 0.05 | | | 0.05 | | | | | |
| | Naphthalenesulfonate | | 0.01 | 0.02 | | | | | | |
| | formaldehyde condensate | | | | | | | | | |
| Component (B′) | Polyacrylic acid | | | | | 0.05 | | 0.05 | | |
| | Polyethylene imine | | | | | | | | | 0.05 |
| Component (C) | Phenylalanine | 0.01 | | 0.005 | | 0.01 | | | | 0.01 |
| | Naphthalenesulfonic acid | | 0.01 | | | | 0.05 | | | |
| (D) Abrasive grains | Colloidal silica | 2.0 | 2.0 | 3.0 | 2.0 | 2 | 2 | 2 | 2 | 2 |
| Oxidizing agent | Hydrogen peroxide | 1 | 1 | 1 | 1 | 1 | 1 | 1 | 1 | 1 |
| pH | | 10.5 | 10.6 | 10.7 | 10.4 | 11 | 10.5 | 11.3 | 10.3 | 11.3 |

Evaluation item

| | | | | | | | | | |
|---|---|---|---|---|---|---|---|---|---|
| Cobalt polishing rate [Å] | Good | Good | Good | Good | Good | Good | Poor | Poor | Good |
| Corrosion of cobalt on | Good | Good | Good | Poor | Poor | Poor | Poor | Poor | Good |
| surface of substrate | | | | | | | | | |
| Surface defect | Good | Good | Good | Good | Good | Poor | Good | Poor | Poor |

The weight-average molecular weights of the polymers shown in Table 1 are as described below.

Styrene-maleic acid copolymer (manufactured by Dai-ichi Kogyo Seiyaku Co., Ltd., product name: DKS Discoat N-10, Mw=3,200)

Styrene-maleic acid half-ester copolymer (manufactured by Dai-ichi Kogyo Seiyaku Co., Ltd., product name: DKS Discoat N-14, Mw=3,600)

Naphthalenesulfonate formaldehyde condensate (manufactured by Dai-ichi Kogyo Seiyaku Co., Ltd., product name: LAVELIN FD-40, Mw=2,700)

Polyacrylic acid (manufactured by Toagosei Co., Ltd., product name: Jurymer AC-10H, Mw=700,000)

As is apparent from Table 1, in the respective cases of using the chemical mechanical polishing compositions according to Examples 1 to 3, the corrosion on the surface of the substrate was suppressed and the number of defects was small while the polishing rate was maintained, and thus satisfactory polishing properties on the surface to be polished were able to be achieved. Meanwhile, in Comparative Examples 1 to 6, the maintenance of the polishing rate and the suppression of the corrosion were not able to be achieved at the same time.

### 3.2. Cleaning Composition

### 3.2.1. Preparation of Cleaning Composition

Ion-exchanged water and components other than potassium hydroxide shown in Table 2 or 3 were put into a vessel made of polyethylene so as to achieve the respective concentrations shown in Table 2 or 3 as a cleaning composition, followed by stirring for 15 minutes. Potassium hydroxide and ion-exchanged water were added to the resultant mixture so that the total amount of all the constituent components was 100 parts by mass, to thereby adjust the resultant to achieve a pH shown in Table 2 or 3. After that, the resultant was filtered with a filter having a pore diameter of 5 μm. Thus, cleaning compositions shown in Tables 2 and 3 were obtained. The pH was measured with a pH meter “F52” manufactured by Horiba, Ltd. In Tables 2 and 3, the “component (B′)” represents a component used as a component other than the component (B) described in Claims instead of or in combination with the component (B).

### 3.2.2. Production of Substrate to be Used in Cleaning Test

### 3.2.2.1. Chemical Mechanical Polishing

An 8-inch wafer in which a cobalt film having a thickness of 2,000 Å was laminated on a silicon substrate was subjected to chemical mechanical polishing with a chemical mechanical polishing apparatus “EPO112” (manufactured by Ebara Corporation) under the following conditions.

Kind of chemical mechanical polishing composition: “CMS7501/CMS7552” manufactured by JSR Corporation

Polishing pad: “IC1000/SUBA400” manufactured by Rodel-Nitta Company

Platen rotation speed: 70 rpm

Head rotation speed 70 rpm

Head load: 50 g/cm²

Supply rate of chemical mechanical polishing composition: 200 mL/min

Polishing time: 60 seconds

### 3.2.2.2. Cleaning

Subsequent to the above-mentioned chemical mechanical polishing, the surface of the substrate after the polishing was subjected to cleaning on a platen and further to brush scrub cleaning under the following conditions.

### <Cleaning on Platen>

Cleaning agent: the cleaning composition prepared above

Head rotation speed: 70 rpm

Head load: 100 g/cm²

Platen rotation speed: 70 rpm

Supply rate of cleaning composition: 300 mL/min

Cleaning time: 30 seconds

### <Brush Scrub Cleaning>

Cleaning agent: the cleaning composition prepared above

Upper brush rotation speed: 100 rpm

Lower brush rotation speed: 100 rpm

Substrate rotation speed: 100 rpm

Cleaning composition supply amount: 300 mL/min

Cleaning time: 30 seconds

### 3.2.3 Evaluation Method

### 3.2.3.1 Evaluation of Defects

The surface of the substrate after the cleaning obtained in the section 3.2.2.2. was measured for the number of defects on the entire surface to be polished with a wafer defect inspection system (KLA 235I, manufactured by KLA-Tencor Corporation). The evaluation criteria are as described below. The results are also shown in Table 2 and Table 3.

Good: A case in which the number of defects on the entire surface of the substrate (diameter: 8 inches) is 250 or less is judged as a satisfactory result.
Poor: A case in which the number of defects on the entire surface of the substrate (diameter: 8 inches) exceeds 250 is judged as an unsatisfactory result.

### 3.2.3.2. Evaluation of Corrosion of Cobalt

Corrosion was evaluated by counting the number of dots on the surface of the substrate after the cleaning obtained in the section 3.2.2.2. through its observation with an optical microscope. The evaluation criteria are as described below. The results are also shown in Table 2 and Table 3.

Good: A case in which the number of dots on the entire surface of the substrate (diameter: 8 inches) is 20 or less is judged as a satisfactory result.
Poor A case in which the number of dots on the entire surface of the substrate (diameter: 8 inches) exceeds 20 is judged as an unsatisfactory result.

### 3.2.3.3. Evaluation of Charge Transfer Resistance

Resistance values were obtained by applying an AC voltage having an amplitude of 5 mV and a frequency of from 0.2 MHz to 0.05 Hz to a cobalt wafer test piece with an end immersed in an aqueous solution from a high frequency to a low frequency with as a measurement device a potentiostat/galvanostat (SI 1287, manufactured by Solartron) and a frequency response analyzer (1252A-type FRA, manufactured by Solartron) connected to each other. More specifically, in the cobalt wafer test piece cut into 1 cm×3 cm, an insulating tape was attached to its middle portion measuring 1 cm×1 cm, an electrode clip was attached to an exposed region measuring 1 cm×1 cm above the middle portion, which was then connected to the measurement device in which the AC voltage was controlled, and another exposed region measuring 1 cm×1 cm below the middle portion was immersed in the cleaning composition obtained above. After the lapse of 2.5 minutes from the beginning of the immersion, an AC voltage having an amplitude of 5 mV and a frequency of from 0.2 MHz to 0.05 Hz was applied thereto from a high frequency to a low frequency. Thus, real part values and imaginary part values of resistance values were obtained. A semicircular plot obtained by plotting the real part values on the ordinate and the imaginary part values on the abscissa was analyzed with AC impedance analysis software “ZView” manufactured by Solartron, and a charge transfer resistance (Ω/cm²) was determined by calculation. The reciprocal of the charge transfer resistance obtained is a value proportional to a cobalt corrosion rate. A case in which this value is 30,000 or more can be judged as a low corrosion rate.

### 3.2.4. Evaluation Results

The compositions of the cleaning compositions, and the evaluation results are shown in Table 2 and Table 3.

TABLE 2

| | | Example | | | | |
|---|---|---|---|---|---|---|
| | | Concentration (mass %) | | | | |
| Cleaning composition | | 4 | 5 | 6 | 7 | 8 |
| Component (A) | Monoethanolamine | 0.02 | 0.03 | 0.02 | 0.02 | 0.03 |
| | Monoisopropanolamine | | | | | |
| Component (B) | Styrene-maleic acid copolymer | 0.001 | 0.001 | 0.01 | 0.001 | |
| | Styrene-maleic acid half-ester | | | | | 0.001 |
| | copolymer | | | | | |
| | Naphthalenesulfonate | | | | | |
| | formaldehyde condensate | | | | | |
| Component (B′) | Polyacrylic acid | | | | | |
| Component (C) | Phenylsuccinic acid | 0.01 | | | | 0.01 |
| | Phenylalanine | | 0.01 | 0.01 | | |
| | Benzoic acid | | | | 0.01 | |
| | Phenyllactic acid | | | | | |
| | Naphthalenesulfonic acid | | | | | |
| pH adjusting agent | Potassium hydroxide | Yes | Yes | Yes | Yes | Yes |
| | pH | 10.6 | 10.8 | 10.8 | 10.6 | 10.6 |

Evaluation item

| | | | | | |
|---|---|---|---|---|---|
| Co impedance [Ω/cm²] | 43,000 | 56,000 | 75,000 | 42,000 | 40,000 |
| | Good | Good | Good | Good | Good |
| Corrosion on surface of | Good | Good | Good | Good | Good |
| substrate | | | | | |
| Number of defects | 79 | 91 | 123 | 90 | 115 |
| [pieces] | Good | Good | Good | Good | Good |

| | | Example | | | |
|---|---|---|---|---|---|
| | | Concentration (mass %) | | | |
| Cleaning composition | | 9 | 10 | 11 | 12 |
| Component (A) | Monoethanolamine | 0.03 | | 0.03 | 0.02 |
| | Monoisopropanolamine | | 0.02 | | |
| Component (B) | Styrene-maleic acid copolymer | | 0.01 | | |
| | Styrene-maleic acid half-ester | | | 0.001 | |
| | copolymer | | | | |
| | Naphthalenesulfonate | 0.001 | | | 0.001 |
| | formaldehyde condensate | | | | |
| Component (B′) | Polyacrylic acid | | | | |
| Component (C) | Phenylsuccinic acid | | | | |
| | Phenylalanine | | | | |
| | Benzoic acid | | | | |
| | Phenyllactic acid | | | | |
| | Naphthalenesulfonic acid | 0.01 | | | |
| pH adjusting agent | Potassium hydroxide | Yes | Yes | Yes | Yes |
| | pH | 10.4 | 10.6 | 11.8 | 11.8 |

| Evaluation item | | | | |
|---|---|---|---|---|
| Co impedance [Ω/cm²] | 42,000 | 52,000 | 35,000 | 40,000 |
| | Good | Good | Good | Good |
| Corrosion on surface of | Good | Good | Good | Good |
| substrate | | | | |
| Number of defects | 189 | 197 | 129 | 154 |
| [pieces] | Good | Good | Good | Good |

TABLE 3

| | | Comparative Example | | | | |
|---|---|---|---|---|---|---|
| | | Concentration (mass %) | | | | |
| Cleaning composition | | 7 | 8 | 9 | 10 | 11 |
| Component (A) | Monoethanolamine | 0.02 | | 0.03 | 0.03 | 0.02 |
| | Monoisopropanolamine | | 0.02 | | | |
| Component (B) | Styrene-maleic acid copolymer | | | | | |
| | Styrene-maleic acid half-ester | | | | | |
| | copolymer | | | | | |
| | Naphthalenesulfonate | | | | | |
| | formaldehyde condensate | | | | | |
| Component (B′) | Polyacrylic acid | | | | | 0.001 |
| Component (C) | Phenylsuccinic acid | | | 0.01 | | |
| | Phenylalanine | | | | 0.01 | |
| | Benzoic acid | | | | | |
| | Phenyllactic acid | | | | | |
| | Naphthalenesulfonic acid | | | | | |
| pH adjusting agent | Potassium hydroxide | Yes | Yes | Yes | Yes | Yes |
| | pH | 11.0 | 10.9 | 10.4 | 10.5 | 10.4 |

Evaluation item

| | | | | | |
|---|---|---|---|---|---|
| Co impedance [Ω/cm²] | 16,000 | 15,000 | 14,000 | 16,000 | 19,000 |
| | Poor | Poor | Poor | Poor | Poor |
| Corrosion on surface of | Poor | Poor | Poor | Poor | Poor |
| substrate | | | | | |
| Number of defects | >500 | >500 | >500 | >500 | 63 |
| [pieces] | Poor | Poor | Poor | Poor | Good |

| | | Comparative Example | | |
|---|---|---|---|---|
| | | Concentration (mass %) | | |
| Cleaning composition | | 12 | 13 | 14 |
| Component (A) | Monoethanolamine | 0.03 | | |
| | Monoisopropanolamine | | | |
| Component (B) | Styrene-maleic acid copolymer | | 0.001 | |
| | Styrene-maleic acid half-ester | | | 0.001 |
| | copolymer | | | |
| | Naphthalenesulfonate | | | |
| | formaldehyde condensate | | | |
| Component (B′) | Polyacrylic acid | 0.001 | | |
| Component (C) | Phenylsuccinic acid | | | 0.01 |
| | Phenylalanine | | | |
| | Benzoic acid | 0.01 | | |
| | Phenyllactic acid | | | |
| | Naphthalenesulfonic acid | | | |
| pH adjusting agent | Potassium hydroxide | Yes | Yes | Yes |
| | pH | 10.6 | 10.6 | 10.6 |

| Evaluation item | | | |
|---|---|---|---|
| Co impedance [Ω/cm²] | 18,000 | 45,000 | 50,000 |
| | Poor | Good | Good |
| Corrosion on surface of | Poor | Good | Good |
| substrate | | | |
| Number of defects | 98 | >500 | >500 |
| [pieces] | Good | Poor | Poor |

The weight-average molecular weights of the polymers shown in the Tables are as described below.

Styrene-maleic acid copolymer (manufactured by Dai-ichi Kogyo Seiyaku Co., Ltd., product name: DKS Discoat N-10, Mw=3,200)

Naphthalenesulfonate formaldehyde condensate (manufactured by Dai-ichi Kogyo Seiyaku Co., Ltd., product name: LAVELIN FD-40, Mw=2,700)

Polyacrylic acid (manufactured by Toagosei Co., Ltd., product name: Jurymer AC-10H, Mw=700,000)

As is apparent from Tables 2 and 3 above, in the respective cases of using the cleaning compositions according to Examples 4 to 12, the corrosion on the surface of the substrate was suppressed, the number of defects was small, and thus satisfactory cleaning properties on the surface to be cleaned were able to be achieved. Meanwhile, in Comparative Examples 7 to 14, the suppression of the corrosion and satisfactory cleaning properties were not able to be achieved at the same time.

The present invention is not limited to the embodiments described above, and various modifications may be made thereto. For example, the present invention encompasses substantially the same configurations as the configurations described in the embodiments (e.g., configurations having the same functions, methods, and results, or configurations having the same objects and effects). In addition, the present invention encompasses configurations obtained by replacing non-essential parts of the configurations described in the embodiments. In addition, the present invention encompasses configurations exhibiting the same action and effect or configurations capable of achieving the same objects as those of the configurations described in the embodiments. In addition, the present invention encompasses configurations obtained by adding known technologies to the configurations described in the embodiments.

### REFERENCE SIGNS LIST

10: low-dielectric-constant insulating film, 11: wiring depression, 12: insulating film, 14: barrier metal film, 16: metal oxide film, 100: object to be treated, 200: wiring board, 200a: surface to be cleaned

1: A treatment composition, comprising:
(A) a water-soluble amine;
(B) a water-soluble polymer comprising an aromatic hydrocarbon group-containing repeating unit, and
an aqueous medium.

2: The treatment composition according to claim 1, further comprising (C) an organic acid comprising an aromatic hydrocarbon group.

3: The treatment composition according to claim 1, wherein the treatment composition has a pH of 9 or more.

4: The treatment composition according to claim 1, wherein the component (A) comprises at least one amine selected from the group consisting of alkanolamines, hydroxylamine, morpholine, morpholine derivatives, piperazine, and piperazine derivatives.

5: The treatment composition according to claim 1, wherein the component (B) comprises a polymer comprising a structural unit derived from alkyl group-substituted or unsubstituted styrene.

6: The treatment composition according to claim 2, wherein the component (C) comprises at least one selected from the group consisting of phenylsuccinic acid, phenylalanine, benzoic acid, phenyllactic acid, and naphthalenesulfonic acid.

7: A treatment method, comprising treating a surface of a wiring board with the treatment composition according to claim 1,
wherein the wiring board comprises, on the surface to be treated:
a wiring material comprising copper or tungsten; and
a barrier metal material comprising at least one selected from the group consisting of tantalum, titanium, cobalt, ruthenium, manganese, and compounds thereof.

8: The treatment method according to claim 7, wherein the surface to be treated comprises a site in which the wiring material and the barrier metal material are brought into contact with each other.

9: The treatment method according to claim 7, wherein the treatment composition cleans the surface to be treated.

10: The treatment composition according to claim 1, further comprising (D) abrasive grains.

11: The treatment composition according to claim 10, wherein the treatment composition is a chemical mechanical polishing composition suitable for polishing the surface to be treated.

12: A chemical mechanical polishing method, comprising polishing the surface to be treated with the treatment composition according to claim 11.

13: A cleaning method, comprising cleaning a surface to be treated with the treatment composition according to claim 1.

14: The treatment composition according to claim 3, further comprising (C) an organic acid comprising an aromatic hydrocarbon group.

15: The treatment composition according to claim 14, further comprising (C) an organic acid comprising an aromatic hydrocarbon group.

16: The treatment composition according to claim 15, wherein the treatment composition has a pH of 9 or more.

17: The treatment composition according to claim 5, further comprising (C) an organic acid comprising an aromatic hydrocarbon group.

18: The treatment composition according to claim 17, wherein the treatment composition has a pH of 9 or more.

19: The treatment method according to claim 9, wherein the surface to be treated comprises a site in which the wiring material and the barrier metal material are brought into contact with each other.

20: The treatment composition according to claim 1, wherein the surface to be treated comprises a site in which the wiring material and the barrier metal material are brought into contact with each other.
